(19) United States
(12) Patent Application Publication
(10) Pub. No.: US 2024/0086581 A1
(43) Pub. Date: Mar. 14, 2024

(54) DEVICE AND PROGRAM FOR THREE-DIMENSIONAL CALCULATION OF RETAINING WALL

(71) Applicant: SANEI CO., LTD., Hiroshima (JP)

(72) Inventor: Makoto YAMAMOTO, Hiroshima (JP)

(73) Assignee: SANEI CO., LTD., Hiroshima (JP)

(21) Appl. No.: 18/238,461

(22) Filed: Aug. 26, 2023

(30) Foreign Application Priority Data
Sep. 8, 2022 (JP) 2022-142619

(51) Int. Cl. G06F 30/13

(52) U.S. Cl. CPC G06F 30/13

(57) ABSTRACT

The present disclosure allows precise calculation of an end position and a shape change point of a retaining wall in three dimensions. A three-dimensional calculation device for a retaining wall includes: an input unit that receives an input of an attribute of the retaining wall; a calculation unit that performs intersection calculation of a retaining wall surface, which is based on the attribute inputted to the input unit, and a terrain surface included in the three-dimensional road model; a placement unit that places a cut slope in a maximum height section of the retaining wall obtained by the intersection calculation by the calculation unit; and a model generator that performs intersection calculation of a cut surface of the cut slope placed by the placement unit and the terrain surface included in the three-dimensional road model to generate a three-dimensional plane model including the cut slope and the retaining wall.

### CROSS-REFERENCE TO RELATED APPLICATION

This application claims priority to Japanese Patent Application No. 2022-142619 filed on Sep. 8, 2022, the entire disclosure of which is incorporated by reference herein.

### BACKGROUND

The present disclosure relates to a device and program for three-dimensional calculation of a retaining wall used for road design, for example.

In recent years, three-dimensional CAD systems have been introduced in various fields to perform design work. Three-dimensional CAD systems have also been introduced in the field of road design. For example, Japanese Patent No. 6848038 discloses a device for automatically placing a retaining wall model on a three-dimensional road model, and Japanese Patent No. 6848031 discloses a device for checking retaining wall stability that executes processing for checking the stability of a retaining wall on a three-dimensional road model.

The automatic placement device of Japanese Patent No. 6848038 is configured to specify a section for placing a retaining wall based on a distance between a center line and a slope on a three-dimensional road model, set a reference line for the placement of the retaining wall in the specified section, place a candidate retaining wall shape in accordance with the reference line, and then automatically adjust the height of the retaining wall.

The stability check device of Japanese Patent No. 6848031 is configured to receive selection of a retaining wall as a target of the stability check on a three-dimensional road model, execute stability check processing for the target retaining wall, and change the color of the retaining wall on the three-dimensional road model based on the result of the stability check.

### SUMMARY

For calculation of a retaining wall by an existing two-dimensional road design technology, an end position and the height of the retaining wall are calculated from a two-dimensional plane and cross sections, based on information items such as road alignment, a longitudinal grade, a cross grade, and a height of shoulders obtained from road width components, and a ground height. Thus, it has been difficult to accurately determine the end position and height of the retaining wall due to inconsistency of them, making a blueprint inappropriate in some cases.

A recent three-dimensional modeling technology for the road design makes a two-dimensional drawing provided by an existing technology directly into a three-dimensional model, making some parts inconsistent. Specifically, it is common in the civil engineering industry to create two-dimensional cross sections at points given at a specified pitch (e.g., a pitch of five or one meter) and connect the cross sections to create a three-dimensional model. Thus, no cross sections are created at any point between the given points because the cross sections are created only at the specified pitch. A three-dimensional model of the retaining wall is also generated by connecting the sections of the retaining wall taken at points given at a specified pitch, and thus no sections are created at any point between the given points. This means that a point where the shape of the retaining wall changes cannot be obtained between the given points, and the end of the retaining wall cannot be obtained when the end position of the retaining wall does not coincide with any of the given points. The resulting three-dimensional product cannot be satisfactory.

In particular, the retaining wall is mainly made of concrete which increases the construction cost. Thus, it is required to calculate the exact quantities of concrete and other ingredients in the design phase. A method that can meet the requirement is preparing a development of the retaining wall. However, the preparation of the development requires obtainment of more accurate positions of the end and shape change point and height of the retaining wall than in earthworks such as making a slope or a flat embankment. Thus, a device that can perform precise three-dimensional calculation of the retaining wall is required. In the current situation, however, the three-dimensional model is generated merely by connecting the cross sections of the retaining wall taken at the specified pitch as described above, which lacks accuracy.

In view of the foregoing, an object of the present disclosure is to enable precise calculation of an end position and a shape change point of a retaining wall in three dimensions.

In order to achieve the object, an aspect of the present disclosure is directed to a three-dimensional calculation device for a retaining wall that automatically calculates a retaining wall on a three-dimensional road model. The three-dimensional calculation device for a retaining wall includes: an input unit that receives an input of an attribute of the retaining wall; a calculation unit that performs intersection calculation of a retaining wall surface, which is based on the attribute inputted to the input unit, and a terrain surface included in the three-dimensional road model; a placement unit that places a cut slope in a maximum height section of the retaining wall obtained by the intersection calculation by the calculation unit; and a model generator that performs intersection calculation of a cut surface of the cut slope placed by the placement unit and the terrain surface included in the three-dimensional road model to generate a three-dimensional plane model including the cut slope and the retaining wall.

Specifically, when the maximum height section of the retaining wall is obtained by the intersection calculation of the retaining wall surface and the terrain surface, the cut slope is placed in the maximum height section of the retaining wall. The intersection calculation of the cut surface of the cut slope and the terrain surface included in the three-dimensional road model allows obtaining a precise shape of an area for placing the retaining wall continuously in three dimensions.

The placement unit can also determine whether the maximum height section of the retaining wall is obtained by the intersection calculation by the calculation unit. When it is determined that the maximum height section of the retaining wall is obtained, it is possible to place the cut slope in the maximum height section of the retaining wall. When it is not determined that the maximum height section of the retaining wall is obtained, it is possible not to place the cut slope in the maximum height section of the retaining wall.

In another aspect of the present disclosure, a three-dimensional calculation device for a retaining wall includes: an input unit that receives an input of an attribute of the retaining wall; a calculation unit that performs calculation of an intersection point to obtain an end-to-end section of a slope when the input unit receives the input of the attribute of the retaining wall; a placement unit that places a retaining wall surface based on the attribute inputted to the input unit in the end-to-end section of the slope obtained by the calculation unit; and a model generator that performs intersection calculation of the retaining wall surface placed by the placement unit and a terrain surface included in the three-dimensional road model in the end-to-end section of the slope to generate a three-dimensional plane model including the slope and the retaining wall.

In this configuration, the intersection calculation of the retaining wall surface based on the attribute inputted to the input unit and the terrain surface included in the three-dimensional road model allows obtaining a precise shape of an area for placing the retaining wall continuously in three dimensions.

Further, the input unit can receive an input of at least a crown width of the retaining wall as the attribute of the retaining wall. When the input unit receives the input of the crown width of the retaining wall, the calculation unit can obtain the end-to-end section of the slope by the calculation of an intersection point.

In another aspect of the present disclosure, a three-dimensional calculation device for a retaining wall includes: an input unit that receives an input of an attribute of the retaining wall; a polyline generator that obtains plane coordinates and a height of a terrain surface included in the three-dimensional road model when the input unit receives the input of the attribute of the retaining wall to generate a three-dimensional polyline; a placement unit that places a retaining wall surface based on the three-dimensional polyline generated by the polyline generator; and a model generator that performs intersection calculation of a slope and the retaining wall surface placed by the placement unit to generate a three-dimensional plane model including the slope and the retaining wall.

In this configuration, when the three-dimensional polyline is generated by obtaining the plane coordinates and height of the terrain surface, the intersection calculation of the slope and the retaining wall surface placed based on the polyline allows obtaining a precise shape of an area for placing the retaining wall continuously in three dimensions.

Further, the input unit can receive an input of at least an embedment width of the retaining wall as the attribute of the retaining wall. The polyline generator can generate the three-dimensional polyline when the input unit receives the input of the embedment width of the retaining wall.

A three-dimensional calculation program for a retaining wall that automatically calculates a retaining wall on a three-dimensional road model can cause a computer to perform: an input step of receiving an input of an attribute of the retaining wall; a calculation step of performing intersection calculation of a retaining wall surface, which is based on the attribute inputted in the input step, and a terrain surface included in the three-dimensional road model; a placement step of placing a cut slope in a maximum height section of the retaining wall obtained by the intersection calculation in the calculation step; and a model generation step of performing intersection calculation of a cut surface of the cut slope placed in the placement step and the terrain surface included in the three-dimensional road model to generate a three-dimensional plane model including the cut slope and the retaining wall.

The present disclosure may also be directed to a three-dimensional calculation method for a retaining wall that automatically calculates a retaining wall on a three-dimensional road model. This method includes: an input step of receiving an input of an attribute of the retaining wall; a calculation step of performing intersection calculation of a retaining wall surface, which is based on the attribute inputted in the input step, and a terrain surface included in the three-dimensional road model; a placement step of placing a cut slope in a maximum height section of the retaining wall obtained by the intersection calculation in the calculation step; and a model generation step of performing intersection calculation of a cut surface of the cut slope placed in the placement step and the terrain surface included in the three-dimensional road model to generate a three-dimensional plane model including the cut slope and the retaining wall

As described above, intersection calculation of a cut surface of a cut slope and a terrain surface allows precise calculation of an end position and a shape change point of the retaining wall in three dimensions.

### BRIEF DESCRIPTION OF THE DRAWINGS

FIG. 1 is a configuration diagram of a three-dimensional calculation device for a retaining wall of an embodiment of the present disclosure.

FIG. 2 is a block diagram of the three-dimensional calculation device for the retaining wall.

FIG. 3 is a diagram showing an example of a three-dimensional road model.

FIG. 4 is a cross-sectional view taken along line IV-IV in FIG. 3.

FIG. 5 is a flowchart of a procedure for generating a three-dimensional road model.

FIG. 6 is a diagram showing an example of road alignment.

FIG. 7 is a diagram showing an example of a user interface screen for setting a road width.

FIG. 8 is a diagram showing an example of a result of intersection calculation of a slope surface and a terrain surface.

FIG. 9 is a flowchart of procedures for three-dimensional calculation processing for a retaining wall.

FIG. 10 is a diagram showing an example of a user interface screen for inputting a retaining wall shape.

FIG. 11 is a diagram showing an example of a user interface screen for inputting a method of embedding the retaining wall in a cutting section.

FIG. 12 is a diagram for explaining a method of embedding the retaining wall in the cutting section.

FIG. 13 is a diagram for explaining the method of embedding the retaining wall in the cutting section with an L-shaped water channel.

FIG. 14 is a diagram showing an example of a user interface screen for inputting a method of placing the retaining wall in the cutting section.

FIG. 15 is a diagram for explaining a case of placing the retaining wall with its height specified.

FIG. 16 is a diagram for explaining a case of placing the retaining wall with a width from road alignment center to a crown of the retaining wall specified.

FIG. 17 is a diagram showing an example of a user interface screen for inputting a method of embedding the retaining wall in an embankment section.

FIG. 18 is a diagram for explaining a case of specifying the placement of the retaining wall based on a depth from a foundation to the terrain.

FIG. 19 is a diagram for explaining a case of specifying the placement of the retaining wall based on a point of intersection of an L-shaped water channel and the terrain.

FIG. 20 is a diagram showing an example of a user interface screen for inputting a method of placing the retaining wall in an embankment section.

FIG. 21 is a diagram for explaining a case of placing the retaining wall directly at a protective shoulder.

FIG. 22 is a diagram for explaining a case of placing the retaining wall with a specified height on the embankment.

FIG. 23 is a diagram for explaining a case of placing the retaining wall with a width from a road alignment center specified.

FIG. 24 is a diagram showing an example of a result of intersection calculation of a retaining wall surface and a terrain surface.

FIG. 25 is a diagram showing an example of a result of intersection calculation of a cut surface and a terrain surface.

FIG. 26 is a transverse cross-sectional view showing a state where cut slopes are placed.

FIG. 27 is a plan view showing a case in which an end-to-end section of a slope is obtained by calculation of an intersection point.

FIG. 28 is a side view showing an example where a three-dimensional polyline is shown.

### DETAILED DESCRIPTION

Embodiments of the present disclosure will be described in detail below with reference to the drawings. It should be noted that the following description of preferred embodiments is merely exemplary in nature and does not intend to limit the present disclosure or applications or use thereof.

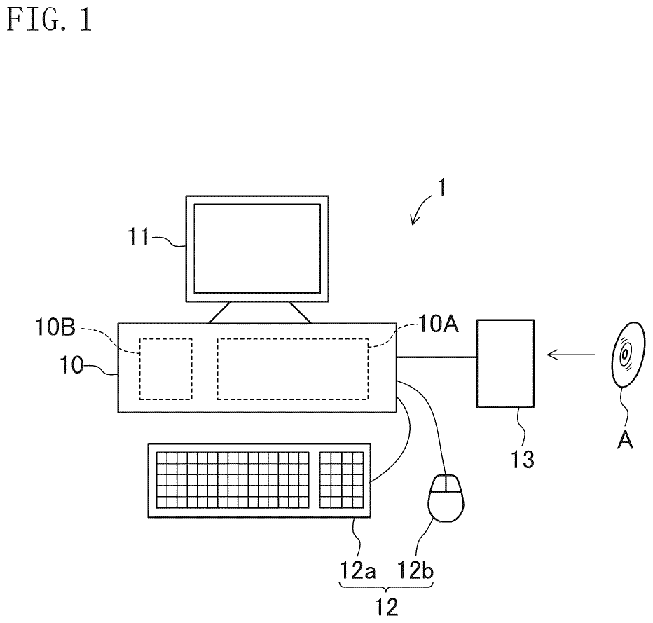

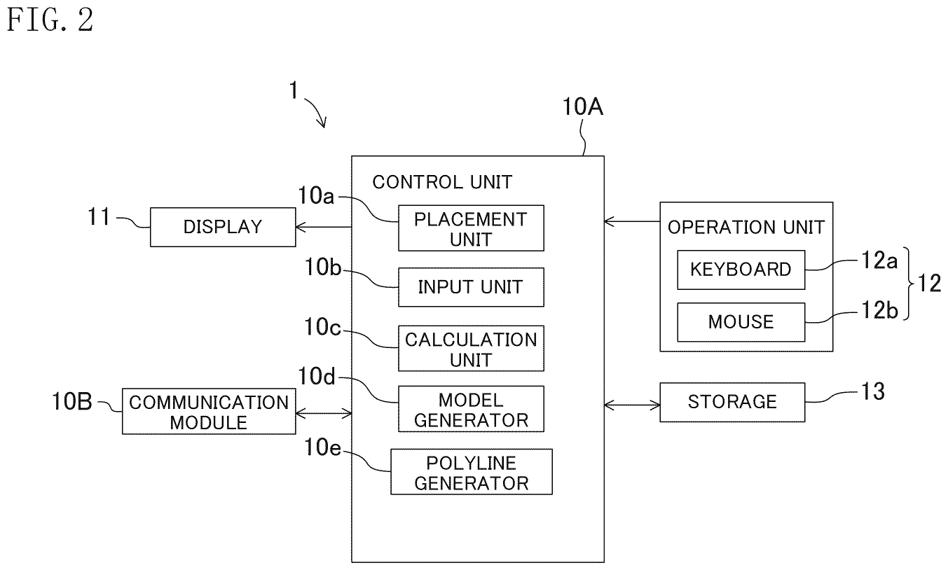

FIG. 1 is a diagram illustrating a configuration of a three-dimensional calculation device 1 for a retaining wall of an embodiment of the present disclosure, and FIG. 2 is a block diagram of the three-dimensional calculation device 1 for the retaining wall. The three-dimensional calculation device 1 for the retaining wall is implemented by a personal computer and includes a body 10, a display 11, an operation unit 12, and a storage 13. The body 10 includes a control unit 10A and a communication module 10B. The control unit 10A includes, for example, a central processing unit (CPU), and a ROM and a RAM (memory) and operates according to a program. The memory is a work memory for developing a program for three-dimensional calculation of the retaining wall when the CPU executes the program, or a buffer memory for temporarily storing data. The communication module 10B communicates with external terminals via, for example, the Internet, and is configured to transmit and receive data.

The control unit 10A includes a placement unit 10a, an input unit 10b, a calculation unit 10c, a model generator 10d, a polyline generator 10e, etc., which will be described later. The placement unit 10a, the input unit 10b, the calculation unit 10c, the model generator 10d, and the polyline generator 10e may be implemented by the hardware constituting the control unit 10A alone or a combination of hardware and software. For example, when the CPU runs the three-dimensional calculation program, the control unit 10A can implement the functions of the placement unit 10a, the input unit 10b, the calculation unit 10c, the model generator 10d, and the polyline generator 10e.

The display 11 is implemented, for example, by a liquid crystal display device or an organic EL display device. The display 11 is connected to and controlled by the control unit 10A and is capable of displaying screens, such as various types of setting screens, an input screen, a design screen, and an analysis screen.

The operation unit 12 is implemented by a device handled by the user to operate the three-dimensional calculation device 1 for the retaining wall. The operation unit 12 includes, for example, a keyboard 12a and a mouse 12b, and may also include a touch screen incorporated in the display 11 or various types of pointing devices. The operation unit 12 is connected to the control unit 10A so that a user's operation on the operation unit 12 can be detected by the control unit 10A.

The storage 13 is implemented by a hard disk drive or a solid-state drive capable of storing various data and programs. The storage 13 is connected to the control unit 10A and stores transmitted data and reads the stored data in accordance with an instruction from the control unit 10A. The storage 13 may be incorporated in the body 10 or may be provided outside the body 10. The storage 13 may be an external server or a so-called cloud storage system. Only part of the storage 13 may be incorporated in the body 10, and the other may be provided outside.

The storage 13 stores a three-dimensional calculation program for a retaining wall that causes a computer to perform the steps described later. The three-dimensional calculation program for the retaining wall may be provided to the user in any format. For example, as illustrated in FIG. 1, the user may be provided with a recording medium A, such as a CD-ROM or a DVD-ROM storing the program, or may download the program from an external server via the Internet. When the provided three-dimensional calculation program for the retaining wall is installed in a general-purpose personal computer, the personal computer can be used as the three-dimensional calculation device 1 for the retaining wall.

Installation of the three-dimensional calculation program for the retaining wall in the general-purpose personal computer may be achieved by installing the program in the storage 13. When the general-purpose personal computer makes access to the external server in which the three-dimensional calculation program for the retaining wall is installed, the personal computer can be used as the three-dimensional calculation device 1 for the retaining wall. The three-dimensional calculation program for the retaining wall can be installed in any location.

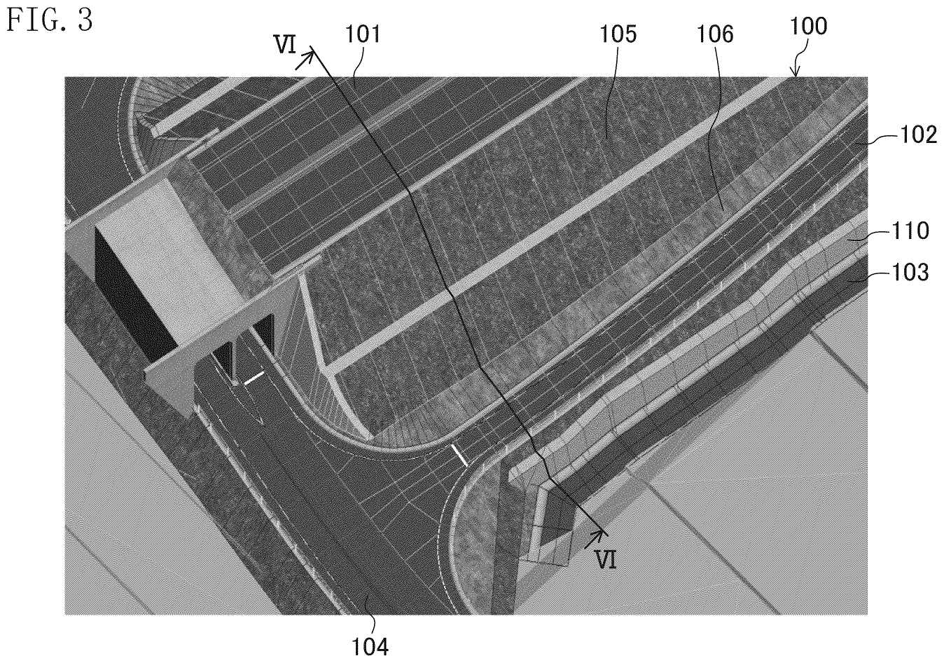

The three-dimensional calculation device 1 for the retaining wall can create a three-dimensional road model 100 as shown in FIG. 3 as an example, by using software for supporting road design and performs processing for automatic calculation of a retaining wall on the created three-dimensional road model 100. Data constituting the three-dimensional road model 100 is stored in, for example, the storage 13. The control unit 10A converts the data read from the storage 13 into an image representing the three-dimensional road model 100 as shown in FIG. 3 and shows the image on the display 11. Thus, the user can check the three-dimensional road model 100 on the display 11. The three-dimensional road model is represented by a color image.

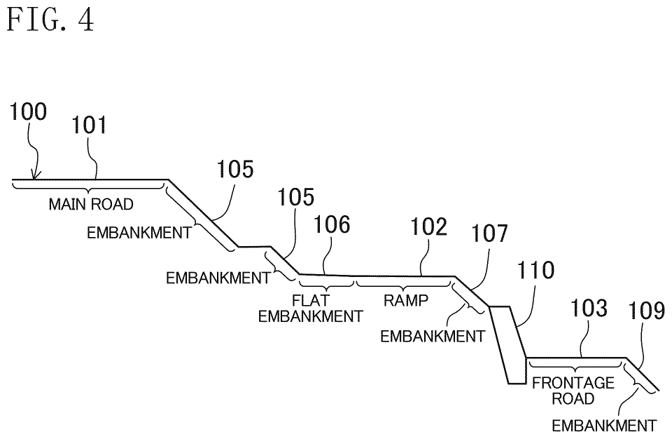

As shown in FIG. 4, the three-dimensional road model 100 includes a main road 101, a ramp (connecting road) 102, a frontage road 103, and an ordinary road 104. The main road 101 is a wide road such as an expressway. The ramp 102 is a road connecting the main road 101 and the ordinary road 104 and narrower than the main road 101. The part of the ramp 102 shown in FIG. 3 is located below the main road 101. The ramp 102 is ascending toward the junction with the main road 101 to approach the main road 101. The frontage road 103 is located below the ramp 102.

Since the ramp 102 is located below the main road 101, an embankment 105 is formed between the main road 101 and the ramp 102. A flat embankment (flat part) 106 is formed between the embankment 105 and the ramp 102. An embankment 107 and a retaining wall 110 are formed between the ramp 102 and the frontage road 103. An embankment 109 is formed on the side of the frontage road 103 opposite to the retaining wall 110.

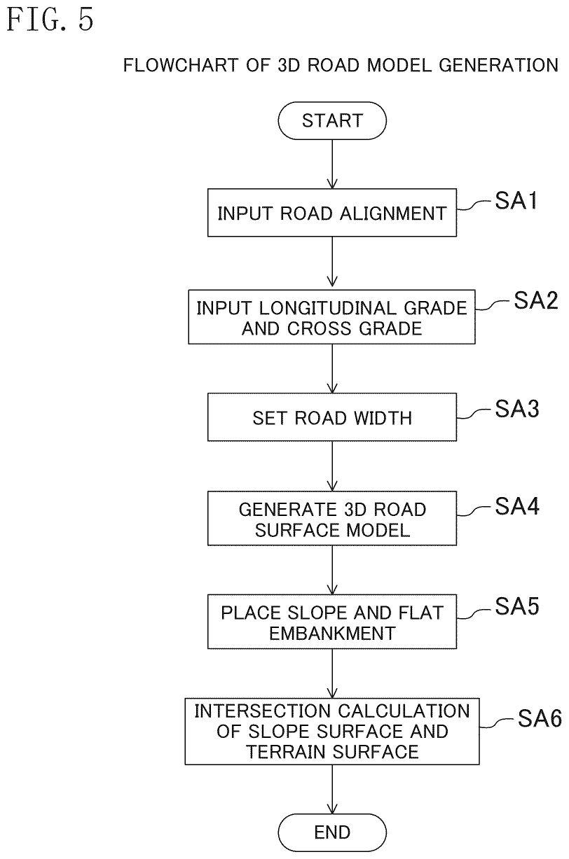

The three-dimensional road model 100 shown in FIG. 3 can be created using known computer-aided design (CAD) software for road design. Specifically, the three-dimensional road model 100 can be created through the procedures of the flowchart shown in FIG. 5 by using the three-dimensional calculation device 1 for the retaining wall in which CAD software for road design is installed.

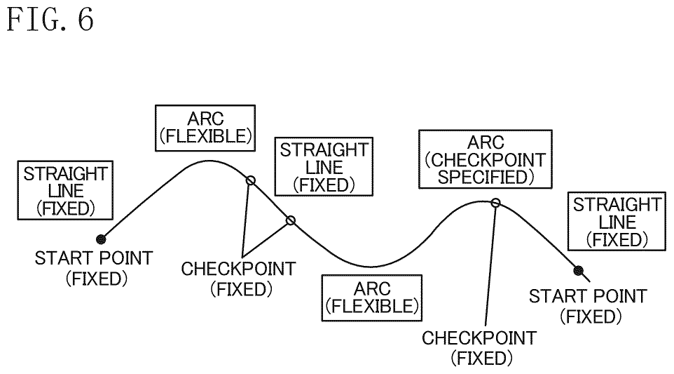

In Step SA1 after the start, the input of road alignment by the user is received. As shown in an example in FIG. 6, the road alignment is formed by a combination of elements, such as a straight line, an arc, and a clothoid curve, and has a fixed start point, a fixed end point, and fixed checkpoints between the start point and the end point that the road alignment should pass. The interval between the fixed points is formed by the combination of the elements.

When inputting the road alignment, the user operates the operation unit 12. The input unit 10b of the control unit 10A detects the operation made on the operation unit 12. The input unit 10b receives the input of the road alignment by detecting the operation on the operation unit 12. The example illustrated in FIG. 3 includes the main road 101, the ramp 102, and the frontage road 103; therefore, the input unit 10b receives the input of the road alignments of the main road 101, the ramp 102, and the frontage road 103. Specifically, the input unit 10b is configured to receive the input of a first road alignment and a second road alignment which are different from each other, thereby making it possible to create the three-dimensional road model 100 based on multiple road alignments.

In Step SA2, an input of a longitudinal grade and a cross grade by the user is received. The longitudinal grade and the cross grade may be inputted via a diagram of a longitudinal sectional shape and a diagram of a cross-sectional shape shown on a screen, or may be inputted by entering numerical values of the grades at different measurement points. In either technique, the input unit 10b receives the input of the longitudinal grade and the cross grade by detecting the operation on the operation unit 12.

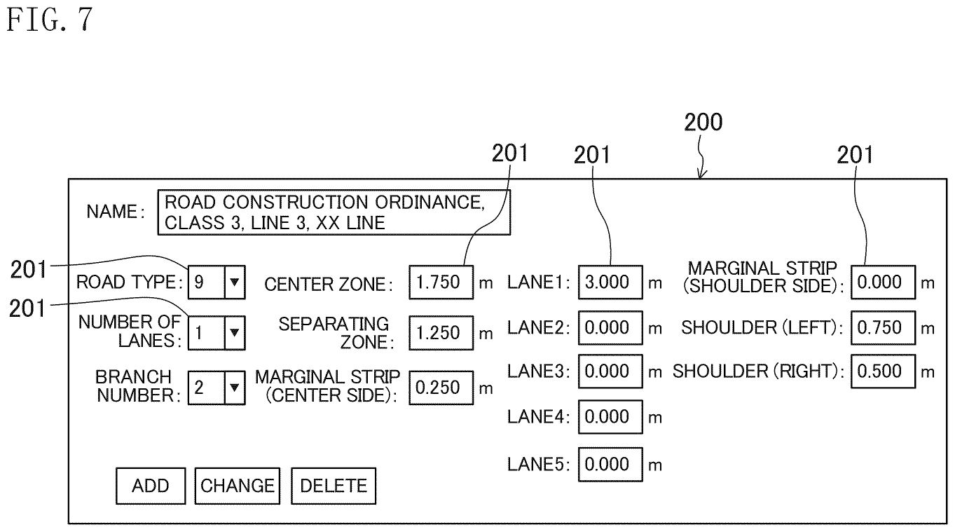

In Step SA3, setting of a road width by the user is received. The road width can be inputted using, for example, a user interface screen 200 for setting the road width shown in FIG. 7. The control unit 10A generates the user interface screen 200 for setting the road width and shows it on the display 11. The user interface screen 200 for setting the road width includes a plurality of input fields 201 that allow the user to separately input a road type, the number of lanes, a center zone, a separating zone, a marginal strip, the width of each lane, a shoulder width, etc. The user can enter any numerical value in each of the input fields 201 by operating the operation unit 12. The input unit 10b receives the input of the road width by detecting the operation on the operation unit 12 and sets the inputted road width.

In Step SA4, the calculation unit 10c creates a three-dimensional road surface model constituting the three-dimensional road model. The three-dimensional road surface model includes road surfaces of the main road 101, the ramp 102, and the frontage road 103 shown as a three-dimensional model.

In Step SA5, a three-dimensional model component in which a grade of a slope, a width of a berm, and a grade of a flat embankment are set is placed on each of the three-dimensional road surface models of the road alignments. Specifically, a point on the three-dimensional road surface model where a slope should be placed is specified, and an instruction is made to place the three-dimensional component of the slope on the specified point. Then, the placement unit 10a places a slope having a three-dimensional shape at the specified point. In a case where the road alignment of the main road 101 is the first road alignment and the road alignment of the ramp 102 is the second road alignment, for example, the placement unit 10a places a slope including the embankment 105 between the first road alignment and the second road alignment. Step SA5 is a slope placement step of placing a slope having a three-dimensional shape on the three-dimensional road model. A berm and a flat embankment are placed in the same manner. Through the above-described steps, a three-dimensional road model where the slope and the flat embankment as shown in FIG. 3 are placed is created.

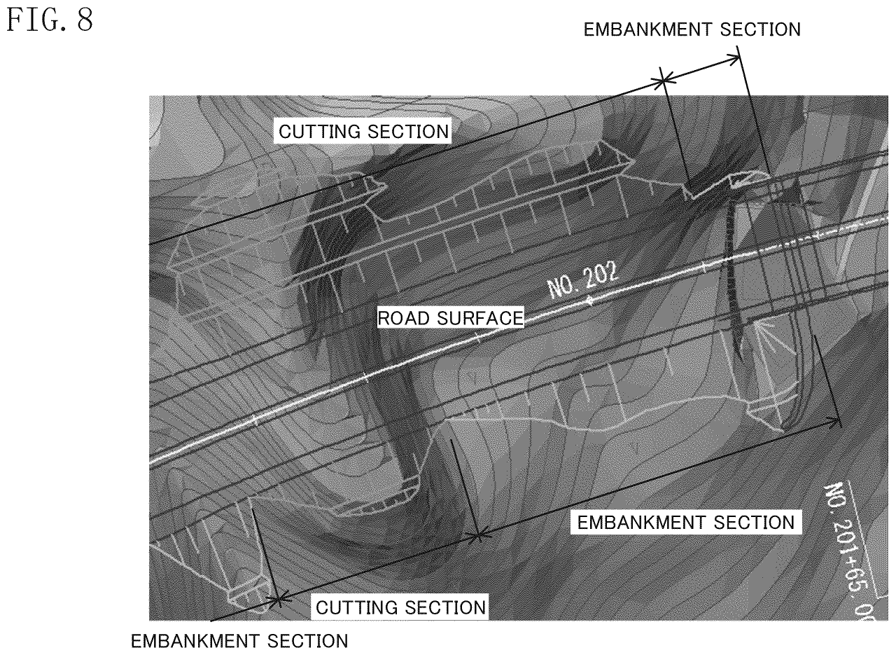

In Step SA6, the calculation unit 10c performs intersection calculation of a slope surface representing the three-dimensional shape of the slope and a terrain surface included in the three-dimensional road model. A cutting section and an embankment section can be obtained by the intersection calculation. FIG. 8 is a diagram showing the result of the intersection calculation of Step SA6, and illustrates examples of the cutting section and the embankment section.

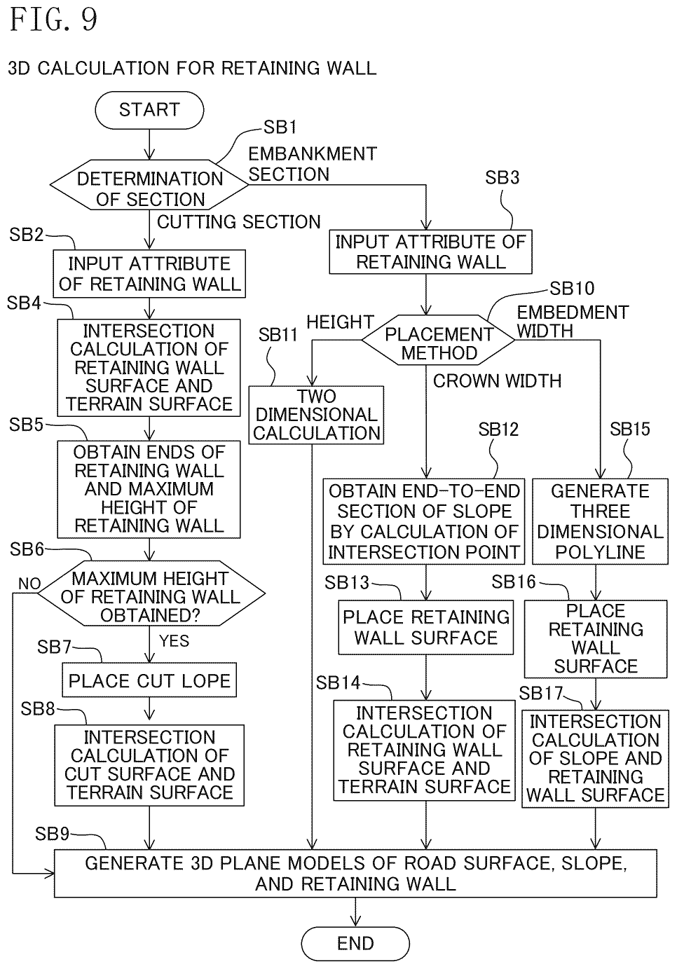

The three-dimensional calculation processing for the retaining wall will be described below with reference to the flowchart shown in FIG. 9. In Step SB1 after the start, it is determined whether a target section for placing the retaining wall is the cutting section or the embankment section. In this determination, the result of the calculation in Step SA6 of the flowchart shown in FIG. 5 is used. When the target section for placing the retaining wall is determined to be the cutting section in Step SB1, the process proceeds to Step SB2. When the target section for placing the retaining wall is determined to be the embankment section, the process proceeds to Step SB3. In Steps SB2 and SB3, the user inputs attributes of the retaining wall. The attributes of the retaining wall include a shape of the retaining wall, a method of embedding the retaining wall, and a method of placing the retaining wall. Thus, the input unit 10b receives the inputs of the shape of the retaining wall, the method of embedding the retaining wall, and the method of placing the retaining wall as the attributes of the retaining wall. This will be specifically described below.

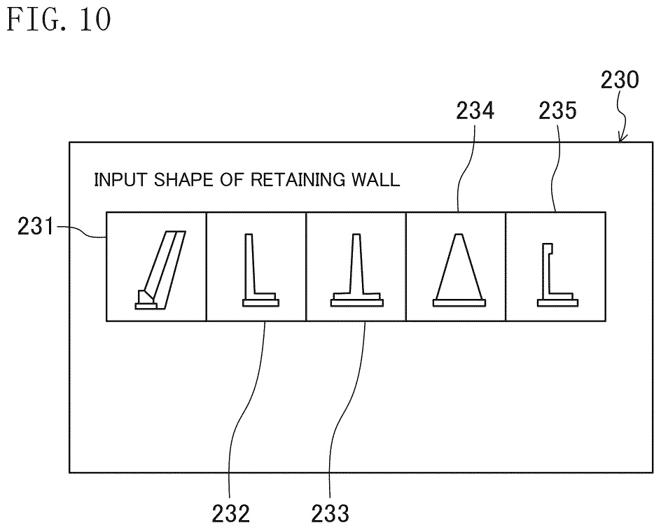

The user can input the shape of the retaining wall by using, for example, a user interface screen 230 for the input of the retaining wall shape shown in FIG. 10. The control unit 10A generates the user interface screen 230 for the input of the retaining wall shape and shows it on the display 11. The user interface screen 230 for the input of the retaining wall shape includes first to fifth icons 231 to 235 each indicating the retaining wall shape. The first icon 231 represents a block retaining wall, the second icon 232 an L-shaped retaining wall, the third icon 233 an inverted T-shaped retaining wall, the fourth icon 234 a gravity retaining wall, and the fifth icon 235 a reinforced earth retaining wall. The input unit 10b detects which one of the first to fifth icons 231 to 235 is selected by the user operating the operation unit 12. By detecting the operation on the operation unit 12, the input unit 10b receives the input of the retaining wall shape selected by the user from among the block retaining wall, the L-shaped retaining wall, the inverted T-shaped retaining wall, the gravity retaining wall, and the reinforced earth retaining wall, and sets the inputted retaining wall shape. The number of choices of the retaining wall shapes is not limited to five shapes described above, and other retaining wall shapes may be inputted. A pull-down menu, for example, may be used in place of the icons for the input of the retaining wall shape.

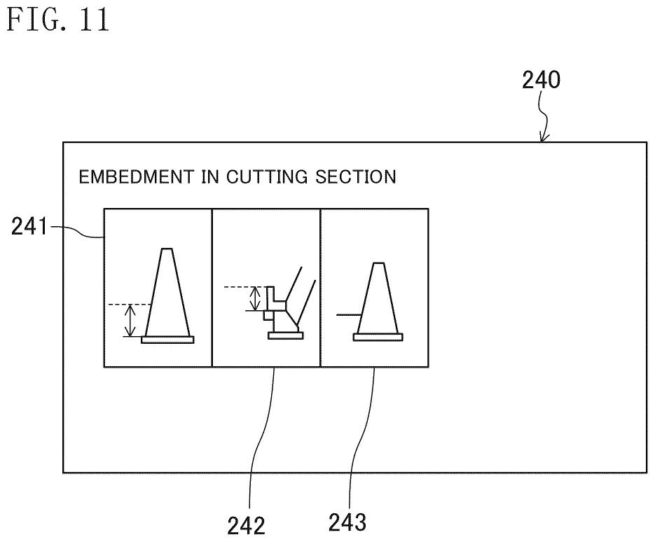

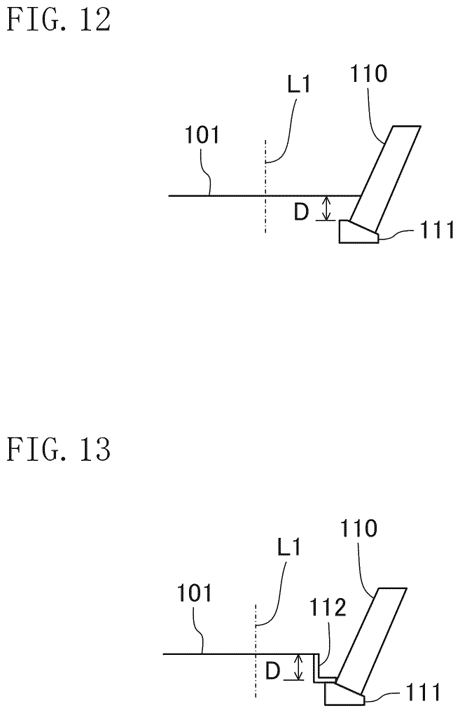

The user can input the method of embedding the retaining wall by using, for example, a user interface screen 240 for the input of the method of embedding the retaining wall in the cutting section shown in FIG. 11. The control unit 10A generates the user interface screen 240 for the input of the method of embedding the retaining wall in the cutting section and shows it on the display 11. The user interface screen 240 for the input of the method of embedding the retaining wall in the cutting section includes a first icon 241 and a second icon 242 each indicating the method of embedding retaining wall in the cutting section. The first icon 241 represents a case of specifying an embedment depth from the road surface (protective shoulder), and a foundation 111 and the embedment depth D of the retaining wall 110 are set as shown in FIG. 12.

As shown in FIG. 13, the second icon 242 indicates the method of embedding the retaining wall 110 in the cutting section in which a water channel, such as an L-shaped water channel 112 or a U-shaped water channel, is formed.

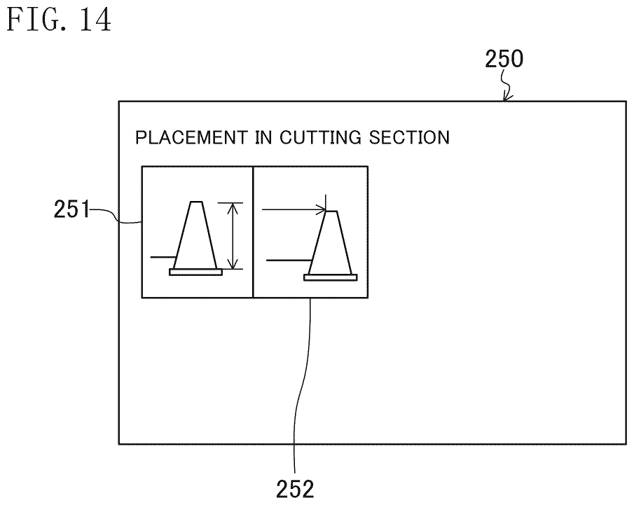

The user can input the method of placing the retaining wall by using, for example, a user interface screen 250 for the input of the method of placing the retaining wall in the cutting section shown in FIG. 14. The control unit 10A generates the user interface screen 250 for the input of the method of placing the retaining wall in the cutting section and shows it on the display 11. The user interface screen 250 for the input of the method of placing the retaining wall in the cutting section includes a first icon 251 and a second icon 252 each indicating the method of placing the retaining wall in the cutting section.

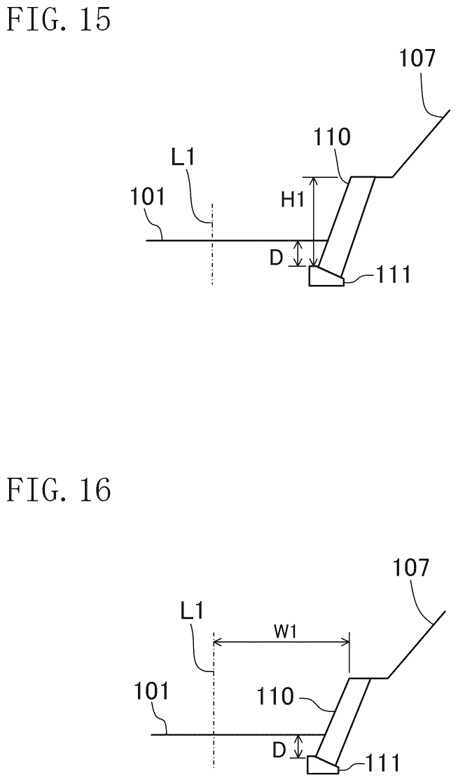

The first icon 251 is selected when the retaining wall with a specified height needs to be placed, and the embedment depth D and height H1 of the retaining wall are set as shown in FIG. 15. The second icon 252 is selected when the retaining wall with a specified width from the road alignment center to the crown of the retaining wall needs to be placed, and the embedment depth D and a distance (width W1) from the road alignment L1 (road alignment center) of the main road 101 to the front edge of the crown of the retaining wall are set as illustrated in FIG. 16.

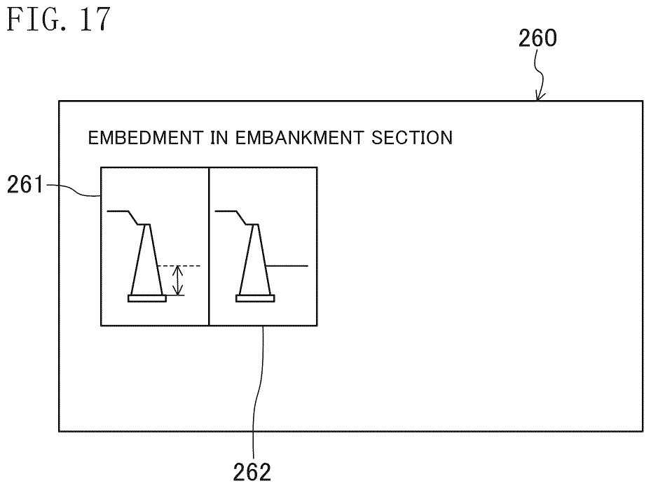

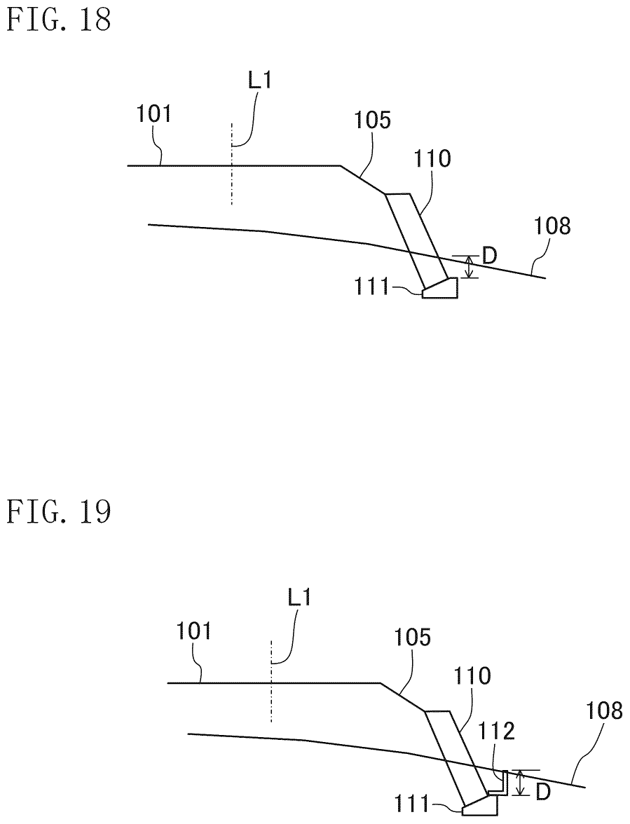

The user can input the method of embedding the retaining wall in the embankment section by using, for example, a user interface screen 260 for the input of the method of embedding the retaining wall in the embankment section shown in FIG. 17. The control unit 10A generates the user interface screen 260 for the input of the method of embedding the retaining wall in the embankment section and shows it on the display 11. The user interface screen 260 for the input of the method of embedding the retaining wall in the embankment section includes a first icon 261 indicating the method of embedding the retaining wall in the embankment section. The first icon 261 allows selection of either one of type 1 specifying a depth from the foundation 111 to the terrain 108 as illustrated in FIG. 18, or type 2 specifying a point of intersection of a water channel, such as an L-shaped water channel 112 and a U-shaped water channel, and the terrain 108 as illustrated in FIG. 19.

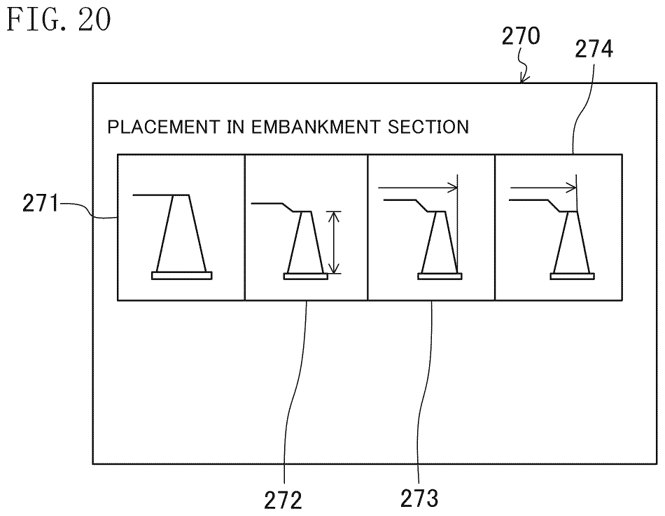

The user can input the method of placing the retaining wall in the embankment section by using, for example, a user interface screen 270 for the input of the method of placing the retaining wall in the embankment section shown in FIG. 20. The control unit 10A generates the user interface screen 270 for the input of the method of placing the retaining wall in the embankment section and shows it on the display 11. The user interface screen 270 for the input of the method of placing the retaining wall in the embankment section includes first to fourth icons 271 to 274 each indicating the method of placing the retaining wall in the embankment section.

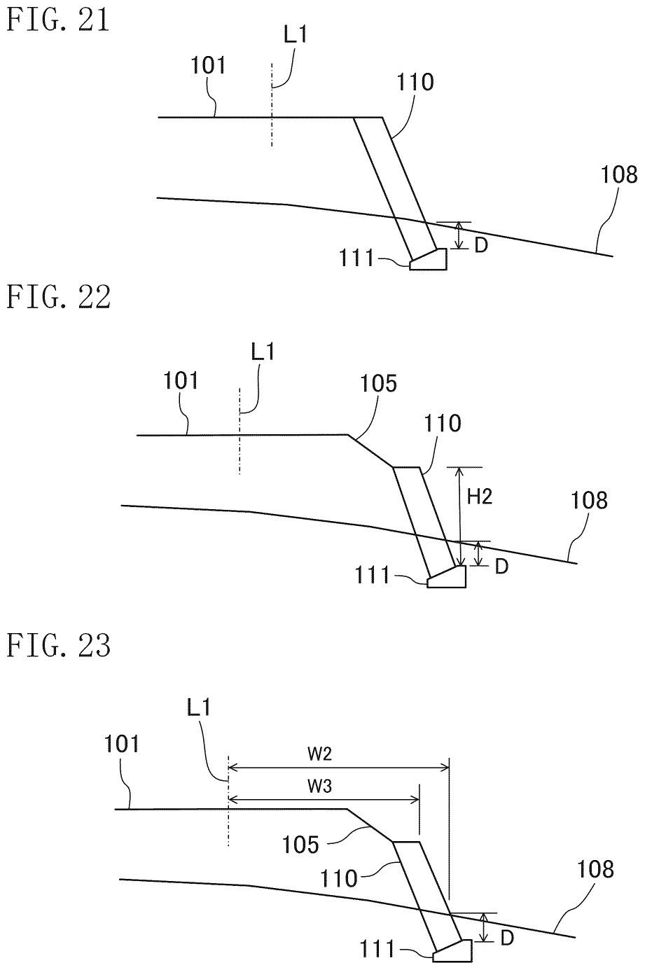

The first icon 271 is selected when the retaining wall is placed directly at the protective shoulder. As shown in FIG. 21, the crown (top surface) of the retaining wall 110 is placed directly at the shoulder of the main road 101, and the point of intersection of the retaining wall 110 placed from the shoulder of the main road 101 and the terrain 108 is calculated.

The second icon 272 is selected when the retaining wall with a specified height is placed on the embankment. The point of intersection of the retaining wall 110 and the embankment 105 is calculated from the height and embedment depth D of the retaining wall 110 as illustrated in FIG. 22.

The third icon 273 is selected when a width W2 from the road alignment center to the point of intersection of the retaining wall 110 and the terrain 108 is specified as illustrated in FIG. 23, and the fourth icon 274 is selected when a width W3 from the road alignment center to the crown of the retaining wall 110 is specified. Specifically, a point of intersection of the terrain 108 and the retaining wall 110 placed with the embankment 105 at the specified width from the road alignment L1 of the main road 101 to the crown or the specified width from the road alignment L1 of the main road 101 to the intersection point is calculated.

Steps SB2 and SB3 of the flowchart shown in FIG. 9 are performed as described above. Each of Steps SB2 and SB3 is an input step of receiving an input of attributes of the retaining wall. After Step SB2, the process proceeds to Step SB4. In Step SB4, the calculation unit 10c performs intersection calculation of a retaining wall surface and a terrain surface. The retaining wall surface can be automatically generated based on the attributes inputted to the input unit 10b. The three-dimensional road model has the terrain surface, which is represented by a reference character 108 in FIGS. 18 and 19, for example. This step is a calculation step of performing intersection calculation of the retaining wall surface and the terrain surface.

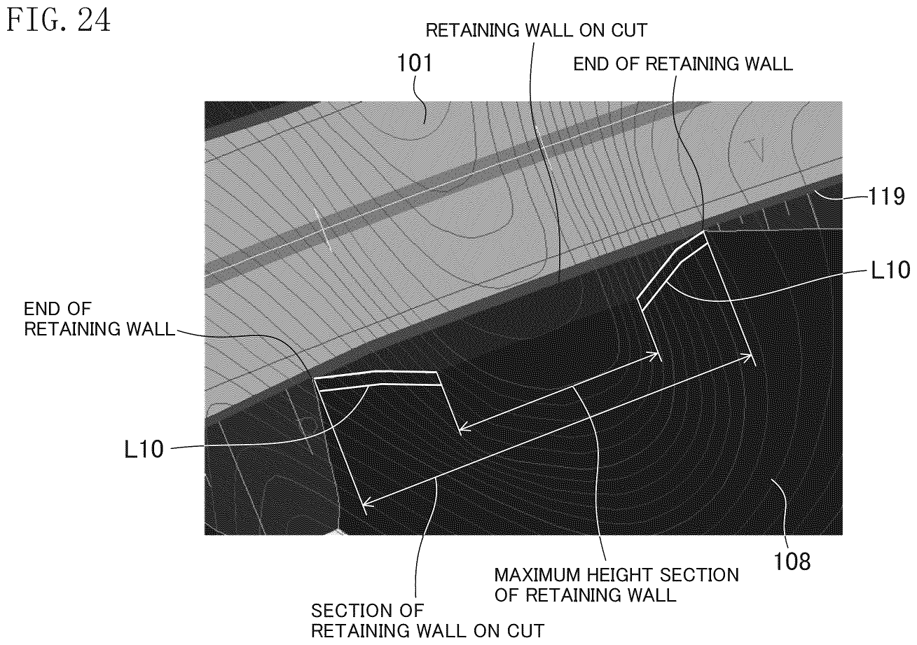

FIG. 24 is a diagram showing an example of a result of the intersection calculation of the retaining wall surface and the terrain surface. The main road 101 is shown in the upper part of FIG. 24, and the terrain 108 is located below the main road 101. The intersection calculation of the retaining wall surface and the terrain surface generates a three-dimensional intersection lines L10 corresponding to the longitudinal edges of the retaining wall (retaining wall on cut). A section between inner ends of the intersection lines L10 is a maximum height section of the retaining wall, and a section between outer ends of the intersection lines L10 is a retaining wall section (retaining wall placement section). An end of the retaining wall is a point of intersection of each of the intersection lines L10 and a shoulder line 119. As described above, it is possible to obtain the maximum height section of the retaining wall, the retaining wall section, and the ends of the retaining wall by the calculation unit 10c performing the intersection calculation of the retaining wall surface and the terrain surface (Step SB5).

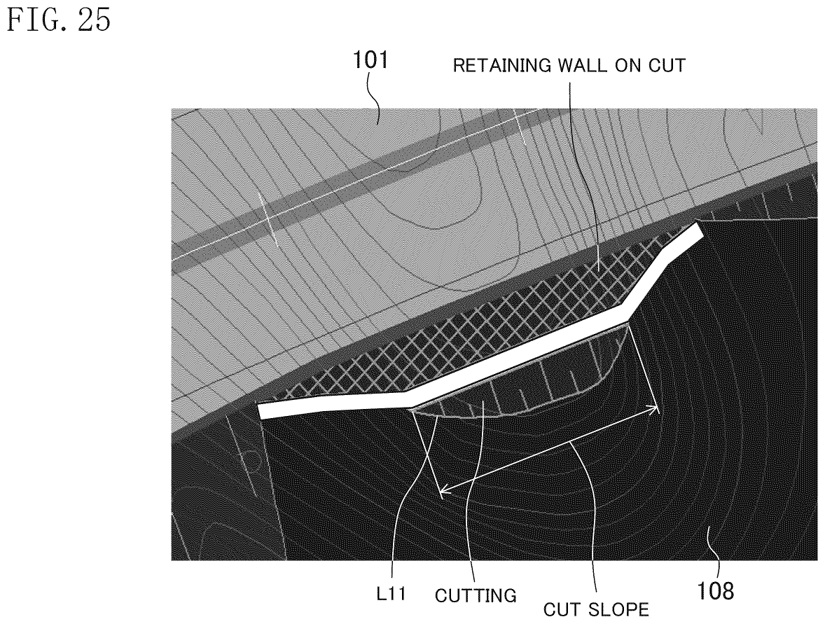

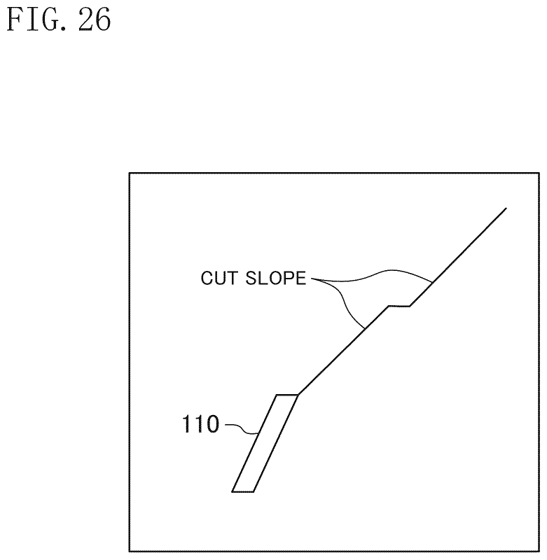

In Step SB6, it is determined whether the maximum height section of the retaining wall is obtained in Step SB5. When it is determined in Step SB6 that the maximum height section of the retaining wall is obtained, the process proceeds to Step SB7. In Step SB7, the placement unit 10a places a cut slope in the maximum height section of the retaining wall obtained by the intersection calculation by the calculation unit 10c (see FIGS. 25 and 26). This step is a placement step of placing the cut slope in the maximum height section of the retaining wall obtained by the intersection calculation in the calculation step.

When it is not determined that the maximum height section of the retaining wall is obtained in Step SB6, the placement unit 10a does not place the cut slope in the maximum height section of the retaining wall, and the process proceeds to Step SB9.

In Step SB8, the model generator 10d performs intersection calculation of a cut surface of the cut slope placed by the placement unit 10a and the terrain surface of the three-dimensional road model. It is thus possible to obtain the three-dimensional shape of the retaining wall continuous in the longitudinal direction.

In Step SB9, the model generator 10d generates a three-dimensional plane model including the road surface, the slope, and the retaining wall. Examples of the three-dimensional plane model include models, such as a model shown as a perspective view, a model shown as a cross-sectional view, a model shown as a plan view, and a model shown as a side view. Each of Steps SB8 and SB9 is a model generation step.

Next, the steps after the target section is determined to be the embankment section in Step SB1 will be described below. When the process proceeds from Step SB3 to Step SB10, a placement method is determined. The placement method is acquired based on the attributes of the retaining wall inputted in Step SB3. When the placement method is based on the “height,” the process proceeds to Step SB11. When the placement method is based on the “crown width,” the process proceeds to Step SB12. When the placement method is based on the “embedment width,” the process proceeds to Step SB15. It is also possible to set “direct placement” as the placement method. If the placement method is the “direct placement,” an end-to-end section is obtained by the intersection calculation of the terrain surface and a front surface of the retaining wall placed from the protective shoulder and the embedment.

In Step SB11, the intersection calculation of the slope, the retaining wall, and the terrain is performed on transverse planes (two dimensional planes) taken at a specified pitch. Thereafter, the process proceeds to Step SB9.

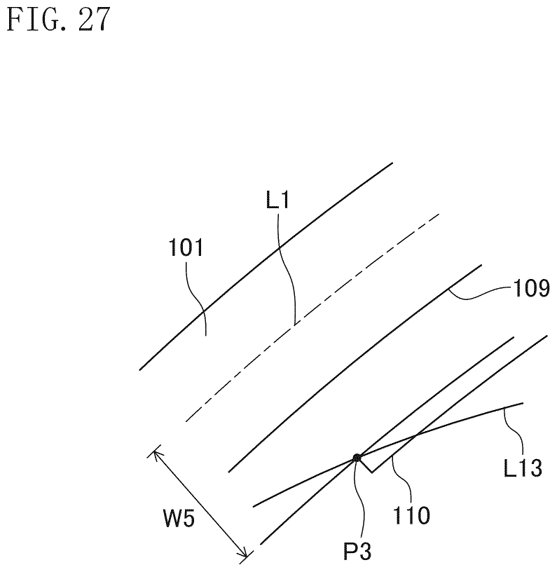

In Step SB12, the calculation unit 10c obtains the end-to-end section of the slope by the calculation of an intersection point based on the width from the road alignment L1 of the main road 101. FIG. 27 is a plan view showing the positional relationship between the shoulder line 119 of the main road 101 and the retaining wall 110, together with a line L13 representing the slope of the embankment. Reference character W5 represents a width from the road alignment L1 to the retaining wall, and an end P3 of the slope can be obtained based on the width W5. Although one end P3 of the slope alone is depicted in this drawing, the other end of the slope (not shown) can also be obtained in the same manner. A section between one end P3 and the other end corresponds to the end-to-end section.

In Step SB13, the placement unit 10a places the retaining wall surface based on the attribute inputted to the input unit 10b in the end-to-end section of the slope obtained by the calculation unit 10c.

In Step SB14, the model generator 10d performs intersection calculation of the retaining wall surface placed by the placement unit 10a and the terrain surface included in the three-dimensional road model in the end-to-end section of the slope. Thereafter, the process proceeds to Step SB9, and the model generator 10d generates the three-dimensional plane model. Every three-dimensional retaining wall model is generated in consideration of the embedment depth or height.

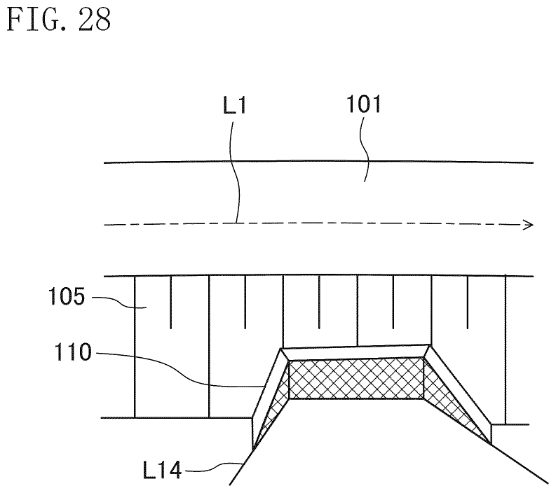

In Step SB15, a three-dimensional polyline is generated. Specifically, as shown in FIG. 28, the polyline generator 10e obtains the plane coordinates and height of the terrain surface included in the three-dimensional road model to generate a three-dimensional polyline L14 indicating the embedment width.

In Step SB16, the placement unit 10a places the retaining wall surface based on the three-dimensional polyline L14 generated by the polyline generator 10e.

In Step SB17, the model generator 10d performs intersection calculation of the slope and the retaining wall surface placed by the placement unit 10a. Thereafter, the process proceeds to Step SB9, and the model generator 10d generates the three-dimensional plane model. The three-dimensional plane model is displayed on the display 11.

As described above, a three-dimensional calculation program for a retaining wall can cause a computer to perform: an input step of receiving an input of an attribute of the retaining wall; a calculation step of performing intersection calculation of a retaining wall surface, which is based on the attribute inputted in the input step, and a terrain surface included in the three-dimensional road model; a placement step of placing a cut slope in a maximum height section of the retaining wall obtained by the intersection calculation in the calculation step; and a model generation step of performing intersection calculation of a cut surface of the cut slope placed in the placement step and the terrain surface included in the three-dimensional road model to generate a three-dimensional plane model including the cut slope and the retaining wall. The use of the three-dimensional calculation device 1 for the retaining wall allows a three-dimensional calculation method for a retaining wall including an input step, a calculation step, a placement step, and a model generation step.

### ADVANTAGES OF EMBODIMENT

According to this embodiment, when the maximum height section of the retaining wall is obtained by the intersection calculation of the retaining wall surface and the terrain surface, the cut slope having the three-dimensional shape can be placed in the maximum height section of the retaining wall. The intersection calculation of the cut surface of the cut slope having the three-dimensional shape and the terrain surface included in the three-dimensional road model allows obtaining a precise shape of an area for placing the retaining wall continuously in three dimensions. Further, the intersection calculation of the retaining wall surface, which is based on the attribute inputted to the input unit 10b, and the terrain surface included in the three-dimensional road model allows obtaining a precise shape of an area for placing the retaining wall continuously in three dimensions. Thus, the user can prepare a precise development of the retaining wall and can obtain the exact quantities of required concrete and other ingredients in the design phase.

The above-described embodiments are merely examples in all respects and should not be interpreted as limiting. All modifications and changes belonging to the equivalent scope of the claims are included in the scope of the present disclosure.

As can be seen in the foregoing description, the device and program for three-dimensional calculation of a retaining wall of the present disclosure can be used for, for example, a road design CAD system.

What is claimed is:

1. A three-dimensional calculation device for a retaining wall that automatically calculates a retaining wall on a three-dimensional road model, the device comprising:
an input unit that receives an input of an attribute of the retaining wall;
a calculation unit that performs intersection calculation of a retaining wall surface, which is based on the attribute inputted to the input unit, and a terrain surface included in the three-dimensional road model;
a placement unit that places a cut slope in a maximum height section of the retaining wall obtained by the intersection calculation by the calculation unit; and
a model generator that performs intersection calculation of a cut surface of the cut slope placed by the placement unit and the terrain surface included in the three-dimensional road model to generate a three-dimensional plane model including the cut slope and the retaining wall.

2. The device of claim 1, wherein
the placement unit determines whether the maximum height section of the retaining wall is obtained by the intersection calculation by the calculation unit, and the placement unit is configured to place the cut slope in the maximum height section of the retaining wall when it is determined that the maximum height section of the retaining wall is obtained, and not to place the cut slope in the maximum height section of the retaining wall when it is not determined that the maximum height section of the retaining wall is obtained.

3. A three-dimensional calculation device for a retaining wall that automatically calculates a retaining wall on a three-dimensional road model, the device comprising:
an input unit that receives an input of an attribute of the retaining wall;
a calculation unit that performs calculation of an intersection point to obtain an end-to-end section of a slope when the input unit receives the input of the attribute of the retaining wall;
a placement unit that places a retaining wall surface based on the attribute inputted to the input unit in the end-to-end section of the slope obtained by the calculation unit; and
a model generator that performs intersection calculation of the retaining wall surface placed by the placement unit and a terrain surface included in the three-dimensional road model in the end-to-end section of the slope to generate a three-dimensional plane model including the slope and the retaining wall.

4. The device of claim 3, wherein
the input unit receives an input of at least a crown width of the retaining wall as the attribute of the retaining wall, and
the calculation unit is configured to obtain the end-to-end section of the slope by the calculation of the intersection point when the input unit receives the input of the crown width of the retaining wall.

5. A three-dimensional calculation device for a retaining wall that automatically calculates a retaining wall on a three-dimensional road model, the device comprising:
an input unit that receives an input of an attribute of the retaining wall;
a polyline generator that obtains plane coordinates and a height of a terrain surface included in the three-dimensional road model when the input unit receives the input of the attribute of the retaining wall to generate a three-dimensional polyline;
a placement unit that places a retaining wall surface based on the three-dimensional polyline generated by the polyline generator; and
a model generator that performs intersection calculation of a slope and the retaining wall surface placed by the placement unit to generate a three-dimensional plane model including the slope and the retaining wall.

6. The device of claim 5, wherein
the input unit receives an input of at least an embedment width of the retaining wall as the attribute of the retaining wall, and
the polyline generator generates the three-dimensional polyline when the input unit receives the input of the embedment width of the retaining wall.

7. A three-dimensional calculation program for a retaining wall that automatically calculates a retaining wall on a three-dimensional road model, the program causing a computer to perform:
an input step of receiving an input of an attribute of the retaining wall;
a calculation step of performing intersection calculation of a retaining wall surface, which is based on the attribute inputted in the input step, and a terrain surface included in the three-dimensional road model;
a placement step of placing a cut slope in a maximum height section of the retaining wall obtained by the intersection calculation in the calculation step; and
a model generation step of performing intersection calculation of a cut surface of the cut slope placed in the placement step and the terrain surface included in the three-dimensional road model to generate a three-dimensional plane model including the cut slope and the retaining wall.
